(19) United States
(12) Patent Application Publication
(10) Pub. No.: US 2025/0011939 A1
(43) Pub. Date: Jan. 9, 2025

(54) ANODIC OXIDATION FILM STRUCTURE

(71) Applicant: POINT ENGINEERING CO., LTD., Chungcheongnam-do (KR)

(72) Inventors: Bum Mo AHN, Gyeonggi-do (KR); Young Heum EOM, Gyeonggi-do (KR); Shin Goo KANG, Gyeonggi-do (KR)

(73) Assignee: POINT ENGINEERING CO., LTD., Chungcheongnam-do (KR)

(21) Appl. No.: 18/712,704

(22) PCT Filed: Nov. 21, 2022
(86) PCT No.: PCT/KR2022/018377

§ 371 Date: May 23, 2024

(30) Foreign Application Priority Data
Nov. 26, 2021 (KR) 10-2021-0165039

(51) Int. Cl. C23C 28/00; C23C 14/16; C25D 5/02; C25D 7/04; C25D 11/24; G01R 1/073

(52) U.S. Cl. CPC C23C 28/345; C23C 14/16; C23C 28/32; C25D 5/022; C25D 7/04; C25D 11/24; G01R 1/07342

(57) ABSTRACT

The present invention provides an anodic oxidation film structure and a manufacturing method therefor, the anodic oxidation film structure comprising: a body made of an anodic oxidization film obtained by anodic oxidation on a parent metal and then removing the parent metal; a through-hole which is formed through the body and has a larger inner width than that of a pore formed during the anodic oxidation; and a metal layer provided on the inner wall of the through-hole, and thus improving the mechanical and/or electrical characteristics of the inner wall of the through-hole.

### TECHNICAL FIELD

The present disclosure relates to an anodic oxidation film structure.

### BACKGROUND

An anodic oxidation film only undergoes a small amount of thermal deformation under a high-temperature atmosphere and has electrical insulating properties. Studies are therefore being conducted to utilize these physical and/or electrical characteristics in various fields.

However, since the anodic oxidation film is manufactured in the form of a thin plate by anodic oxidation of a metal base material, it is highly likely to undergo brittle fracture after the metal base material is removed. Therefore, in order to use the anodic oxidation film as a structure, the problem of brittle fracture needs to be overcome.

In particular, when forming a perforated hole that vertically pass through the anodic oxidation film and inserting a sliding member into the inner wall of the perforated hole, brittle fracture easily occurs in the inner wall of the perforated hole.

Meanwhile, the anodic oxidation film has electrical insulating properties. Therefore, in an anodic oxidation film structure using the anodic oxidation film, consideration has to be given to how to implement a configuration to provide at least partial conductivity in addition to the insulating properties.

Using the anodic oxidation film with the perforated hole as a structure thus requires improving the mechanical and/or electrical characteristics of the perforated hole.

### DOCUMENTS OF RELATED ART

### Patent Documents

(Patent Document 1) Korean Patent Application Publication No. 10-2017-0068241

### SUMMARY

### Technical Problem

Accordingly, the present disclosure has been made keeping in mind the above problems occurring in the related art, and an objective of the present disclosure is to provide an anodic oxidation film structure and a method of manufacturing the same that improve the mechanical and/or electrical characteristics of an inner wall of a perforated hole.

### Technical Solution

In order to accomplish the above objective, according to one aspect of the present disclosure, there is provided an anodic oxidation film structure, including: a body made of an anodic oxidation film formed by anodic oxidation of a base metal and then removing the base metal; a perforated hole formed through the body and having a larger inner width than pores formed during the anodic oxidation; and a metal layer provided on an inner wall of the perforated hole.

In addition, the metal layer may include: a first metal layer provided on the inner wall of the perforated hole; and a second metal layer provided on an inner wall of the first metal layer.

In addition, the inner wall of the perforated hole may be provided with a plurality of fine trenches in which a plurality of peaks and a plurality of valleys are repeated in a circumferential direction of the perforated hole. The first metal layer may entirely cover the fine trenches.

In addition, the first metal layer may be made of a single layer or a plurality of layers of titanium (Ti), copper (Cu), gold (Au), or nickel (Ni).

In addition, the second metal layer may be made of at least one metal selected from: the group consisting of rhodium (Rd), platinum (Pt), iridium (Ir), palladium (Pd), nickel (Ni), manganese (Mn), tungsten (W), phosphorus (Ph), cobalt (Co), and an alloy of these metals; the group consisting of a palladium-cobalt (PdCo) alloy and a palladium-nickel (PdNi) alloy: the group consisting of a nickel-phosphorus (NiPh) alloy, a nickel-manganese (NiMn) alloy, a nickel-cobalt (NiCo) alloy, and a nickel-tungsten (NiW) alloy: or the group consisting of copper (Cu), silver (Ag), gold (Au), and an alloy of these metals.

Meanwhile, according to another aspect of the present disclosure, there is provided a method manufacturing an anodic oxidation film structure, the method including: forming a perforated hole in a body made of an anodic oxidation film; and forming a metal layer on an inner wall of the perforated hole.

In addition, the forming of the perforated hole in the body made of the anodic oxidation film may include: forming an opening area by forming a patternable material on a surface of the body made of the anodic oxidation film and then patterning the patternable material; and forming the perforated hole by removing the body made of the anodic oxidation film in the opening area using an etchant.

In addition, the forming of the metal layer may include: forming a first metal layer on a surface of the patternable material and the inner wall of the perforated hole; forming a second metal layer on the first metal layer so that a through-hole is provided; and removing the patternable material and the first metal layer and the second metal layer outside the through-hole so that the first metal layer and the second metal layer exist only inside the through-hole.

### Advantageous Effects

The present disclosure can provide an anodic oxidation film structure and a method of manufacturing the same that improve the mechanical and/or electrical characteristics of an inner wall of a perforated hole.

### DESCRIPTION OF DRAWINGS

FIG. 1 is a plan view illustrating an anodic oxidation film structure according to a preferred embodiment of the present disclosure.

FIG. 2 is a view illustrating a section cut along line A-A′ of FIG. 1.

FIG. 3 is a sectional view illustrating a body made of an anodic oxidation film according to a preferred embodiment of the present disclosure.

FIG. 4 is a view illustrating an opening area is formed by forming a patternable material on first and second surfaces of the body made of the anodic oxidation film and then patterning the patternable material according to the preferred embodiment of the present disclosure.

FIG. 5 is a view illustrating a perforated hole is formed by removing the body made of the anodic oxidation film in the opening area using an etchant according to the preferred embodiment of the present disclosure.

FIG. 6 is a plan view illustrating the body made of the anodic oxidation film in which the perforated hole is formed according to the preferred embodiment of the present disclosure.

FIG. 7 is a view illustrating a first metal layer is formed on a surface of the patternable material and an inner wall of the perforated hole according to the preferred embodiment of the present disclosure.

FIG. 8 is a plan view illustrating the first metal layer is formed on the inner wall of the perforated hole according to the preferred embodiment of the present disclosure.

FIG. 9 is a view illustrating the first metal layer formed on the inner wall of the perforated hole is left, with the patternable material and the first metal layer formed on the surface of the patternable material removed according to the preferred embodiment of the present disclosure.

FIG. 10 is a view illustrating a second metal layer is formed on a surface of the first metal layer according to the preferred embodiment of the present disclosure.

FIG. 11 is a view illustrating an insertion member is inserted into a through-hole according to the preferred embodiment of the present disclosure.

FIG. 12 is a view illustrating a bonding layer is formed inside the first metal layer according to the preferred embodiment of the present disclosure.

### DETAILED DESCRIPTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are clearly intended for the purpose of understanding the concept of the present disclosure, and one should understand that the present disclosure is not limited the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, thicknesses of films and regions in the figures may be exaggerated. As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. The technical terms used herein are for the purpose of describing particular embodiments only and should not be construed as limiting the present disclosure. As used herein, the singular forms are intended to include the plural forms as well, unless the context clearly indicates otherwise. It will be further understood that the terms “comprise” and/or “include” when used in this specification, specify the presence of stated features, integers, steps, operations, elements, components, and/or combinations thereof but do not preclude the presence or addition of one or more other features, integers, steps, operations, elements, components, and/or combinations thereof.

Hereinafter, preferred embodiments of the present disclosure will be described in detail with reference to the accompanying drawings.

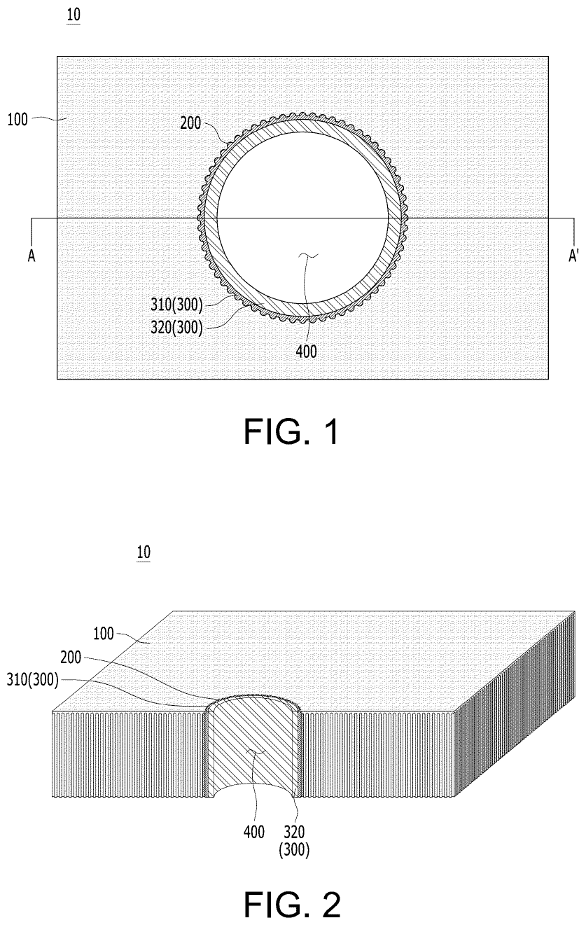

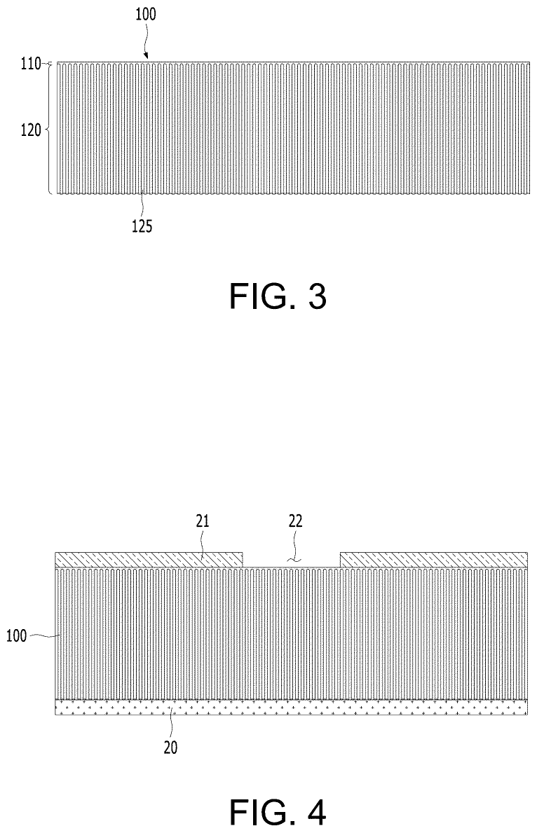

FIG. 1 is a plan view illustrating an anodic oxidation film structure according to a preferred embodiment of the present disclosure. FIG. 2 is a view illustrating a section cut along line A-A′ of FIG. 1. FIGS. 3 to 10 are views illustrating a process of manufacturing an anodic oxidation film structure according to a preferred embodiment of the present disclosure. FIG. 11 is a view illustrating an insertion member is inserted into a through-hole.

The anodic oxidation film structure 10 includes a body 100 made of an anodic oxidation film, a perforated hole 200 formed through the body 100, and a metal layer 300 provided on an inner wall of the perforated hole 200.

The body 100 is made of the anodic oxidation film. The anodic oxidation film means a film formed by anodic oxidation of a metal as a base material, and pores 125 mean holes formed in the process of forming the anodic oxidation film by the anodic oxidation of the metal. For example, in a case where the metal as the base material is aluminum (Al) or an aluminum alloy, the anodic oxidation of the base material forms the anodic oxidation film consisting of anodized aluminum (Al₂O₃) on a surface of the base material. However, the metal as the base material is not limited thereto and includes Ta, Nb, Ti, Zr, Hf, Zn, W, Sb, or an alloy of these metals. The resulting anodic oxidation film includes a barrier layer 110 in which no pores 125 are formed therein vertically and a barrier layer 120 in which pores 125 are formed therein. After removing the base material on which the anodic oxidation film including the barrier layer 110 and the porous layer 120 is formed, only the anodic oxidation film consisting of anodized aluminum (Al₂O₃) remains. The anodic oxidation film may have a structure in which the barrier layer 110 formed during the anodic oxidation is removed to expose the top and bottom of the pores 125, or a structure in which the barrier layer 110 formed during the anodic oxidation remains to close one of the top and bottom of the pores 125.

The anodic oxidation film has a coefficient of thermal expansion of 2 to 3 ppm/° C. With this range, the anodic oxidation film is less likely to undergo thermal deformation due to temperature when exposed to a high-temperature environment. Thus, even when the anodic oxidation film structure 10 is used in a high-temperature environment, it can be used without thermal deformation.

The body 100 includes the perforated hole 200 formed through the body 100 and having a larger inner width than the pores 125 formed during the anodic oxidation.

The perforated hole 200 is formed through upper and lower surfaces of the body 100.

The perforated hole 200 may have a circular cross-sectional shape as illustrated. However, the cross-sectional shape of the perforated hole 200 is not limited thereto, and may include various shapes, including polygonal.

The metal layer 300 is provided on the inner wall of the perforated hole 200. The metal layer 300 is provided in the form of a thin film along the inner wall of the perforated hole 200 so as not to seal the perforated hole 200, thereby forming the through-hole 400.

The metal layer 300 may be made of at least one metal selected from: the group consisting of rhodium (Rd), platinum (Pt), iridium (Ir), palladium (Pd), nickel (Ni), manganese (Mn), tungsten (W), phosphorus (Ph), titanium (Ti), cobalt (Co), copper (Cu), silver (Ag), gold (Au), and an alloy of these metals; the group consisting of a palladium-cobalt (PdCo) alloy and a palladium-nickel (PdNi) alloy: or the group consisting of a nickel-phosphorus (NiPh) alloy, a nickel-manganese (NiMn) alloy, a nickel-cobalt (NiCo) alloy, and a nickel-tungsten (NiW) alloy.

When the metal layer 300 is made of a metal having high wear resistance or hardness, the mechanical characteristics of an inner wall of the through-hole 400 of the anodic oxidation film structure 10 can be improved. With this, it is possible to solve the problem of the inner wall of the through-hole 400 undergoing brittle fracture due to friction with the insertion member 500.

Meanwhile, when the metal layer 300 is made of a metal having high electrical conductivity, the electrical characteristics of the inner wall of the through-hole 400 of the anodic oxidation film structure 10 can be improved. The body 100 made of the anodic oxidation film has electrical insulating properties, and the inner wall of the through-hole 400 has electrical conductive properties, so that a current path may be formed through the through-hole 400.

The metal layer 300 includes a first metal layer 310 and a second metal layer 320. The first metal layer 310 is provided on the inner wall of the perforated hole 200, and the second metal layer 320 is provided on an inner wall of the first metal layer 310.

The first metal layer 310 may be formed to have a thickness in the range of 0.01 μm to 1 μm. The first metal layer 310 is made of a single layer or a plurality of layers of titanium (Ti), copper (Cu), gold (Au), or nickel (Ni). The first metal layer 310 is made of a metal having excellent bonding force with the second metal layer 320.

The second metal layer 320 may be formed to have a thickness in the range of 0.1 μm to 10 μm, and may be formed to be thicker than the first metal layer 310. The second metal layer 320 may be made of a metal having high wear resistance or hardness. The second metal layer 320 may be made of at least one metal selected from: the group consisting of rhodium (Rd), platinum (Pt), iridium (Ir), palladium (Pd), nickel (Ni), manganese (Mn), tungsten (W), phosphorus (Ph), titanium (Ti), cobalt (Co), and an alloy of these metals; the group consisting of a palladium-cobalt (PdCo) alloy and a palladium-nickel (PdNi) alloy: or the group consisting of a nickel-phosphorus (NiPh) alloy, a nickel-manganese (NiMn) alloy, a nickel-cobalt (NiCo) alloy, and a nickel-tungsten (NiW) alloy. When the second metal layer 320 is made of a metal having high wear resistance or hardness, the mechanical characteristics of the inner wall of the through-hole 400 of the anodic oxidation film structure 10 can be improved. With this, it is possible to solve the problem of the inner wall of the through-hole 400 undergoing brittle fracture due to friction with the insertion member 500.

Meanwhile, the second metal layer 320 may be made of a metal having high electrical conductivity. For example, it is made of at least one metal selected from the group consisting of copper (Cu), silver (Ag), gold (Au), and an alloy of these metals. When the second metal layer 320 is made of a metal having high electrical conductivity, the electrical characteristics of the inner wall of the through-hole 400 of the anodic oxidation film structure 10 can be improved. The body 100 made of the anodic oxidation film has electrical insulating properties, and the inner wall of the through-hole 400 has electrical conductive properties, so that a current path may be formed through the through-hole 400.

The inner wall of the perforated hole 200 is provided with a plurality of fine trenches 88 in which a plurality of peaks and a plurality of valleys are repeated in the circumferential direction of the perforated hole 200.

The fine trenches 88 are formed such that the peaks and the valleys extend in the longitudinal direction of the perforated hole 200 and the peaks and the valleys are repeated in the circumferential direction of the perforated hole 200. The fine trenches 88 have a depth in the range of 20 nm to 1 μm and a width in the range of 20 nm to 1 μm. Here, because the fine trenches 88 are resulted from the formation of the pores 125 formed during the manufacture of the body 100 made of the anodic oxidation film, the width and depth of the fine trenches 88 are equal to or less than the diameter of the pores 125 formed in the body 100 made of the anodic oxidation film. On the other hand, in the process of forming the perforated hole 100 in the body 100 made of the anodic oxidation film, portions of the pores 125 may be crushed by an etching solution to at least partially form a fine trench 88 having a depth greater than the diameter of the pores 125 formed during the anodic oxidation.

Due to the structure of the fine trenches 88 in which the peaks and the valleys are repeated in the circumferential direction, when the inner wall of the perforated hole 200 is not protected by the metal layer 300, fine particles made of the anodic oxidation film may be generated on the inner wall of the perforated hole 200 due to friction with a member inserted into the perforated hole 200. On the other hand, according to the preferred embodiment of the present disclosure, since the inner wall of the perforated hole 200 is protected by the metal layer 300, even when the insertion member 500 sliding inside the through-hole 400 is inserted into the through-hole 400, fine particles made of the anodic oxidation film may not be generated.

The first metal layer 310 entirely covers the fine trenches 310 so that the fine trenches 88 are not exposed toward the second metal layer 320. Through the configuration in which the fine trenches 88 are provided on a side surface of the perforated hole 200, the bonding force between the body 100 and the first metal layer 310 can be improved. Therefore, even when a shear force to separate the body 100 and the first metal layer 310 occurs at the interface between the body 100 and the first metal layer 310, the first metal layer 310 can be effectively prevented from being separated from the body 100 through the configuration of the fine trenches 88.

The bonding force of the second metal layer 320 is higher with the first metal layer 310 than with the body 100 made of the anodic oxidation film. Since the first metal layer 310 entirely covers the inner wall of the perforated hole 200 so that the fine trenches 88 are not exposed and the second metal layer 320 is formed on the surface of the first metal layer 310, the second metal layer 320 can also be firmly coupled to the body 100.

The first metal layer 310 is formed by filling the valleys of the fine trenches 88, so that the peaks and the valleys are removed at the interface between the first metal layer 310 and the second metal layer 320. As a result, when the insertion member 500 slides vertically inside the through-hole 400, the generation of fine particles from the second metal layer 320 can be minimized.

Hereinafter, the process of manufacturing the anodic oxidation film structure 10 according to the preferred embodiment of the present disclosure will be described with reference to FIGS. 3 to 10.

A method of manufacturing an anodic oxidation film structure 10 includes forming a perforated hole 200 in a body 100 made of an anodic oxidation film, and forming a metal layer 300 on an inner wall of the perforated hole 200.

The forming of the perforated hole 200 in the body 100 made of the anodic oxidation film includes (i) forming an opening area 22 by forming a patternable material 21 on a surface of the body 100 made of the anodic oxidation film and then patterning the patternable material 21 and (ii) forming the perforated hole 200 by removing the body 100 made of the anodic oxidation film in the opening area 22 using an etchant.

First, the forming of the opening area 22 by patterning the patternable material 21 on the surface of the body 100 made of the anodic oxidation film and then patterning the patternable material 21 is performed.

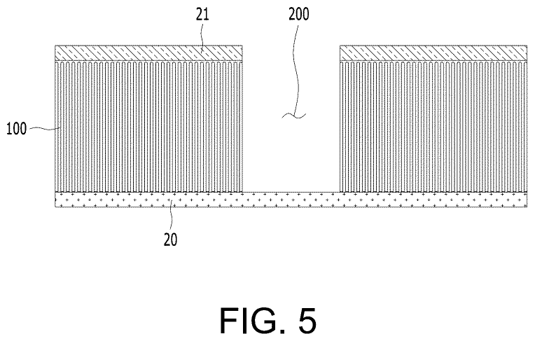

FIG. 3 is a sectional view illustrating the body 100 made of the anodic oxidation film. FIG. 4 is a view illustrating the opening area 22 is formed by forming the patternable material 21 on the surface of the body 100 made of the anodic oxidation film and then patterning the patternable material 21.

Referring to FIG. 3, the body 100 made of the anodic oxidation film is formed by anodic oxidation of a base metal and then removing the base metal. Pores 125 mean holes formed in the process of forming the anodic oxidation film by anodic oxidation of the base metal. The body 100 includes a barrier layer 110 in which no pores 125 are formed therein and a porous layer 120 in which pores 125 are formed therein. The body 100 illustrated in FIGS. 3 and 4 has a structure in which the top of the pores 125 formed during the anodic oxidation is closed by the barrier layer 110.

Referring to FIG. 4, the opening area 22 is formed by forming the patternable material 21 on the surface (upper surface) of the body 100 made of the anodic oxidation film and then patterning the patternable material 21. The patternable material 21 may be a photoresist, but is not limited thereto. A support substrate (not illustrated) is provided under the body 100 to improve handling of the body.

Then, the forming of the perforated hole 200 by removing the body 100 made of the anodic oxidation film in the opening area 22 using the etchant is performed.

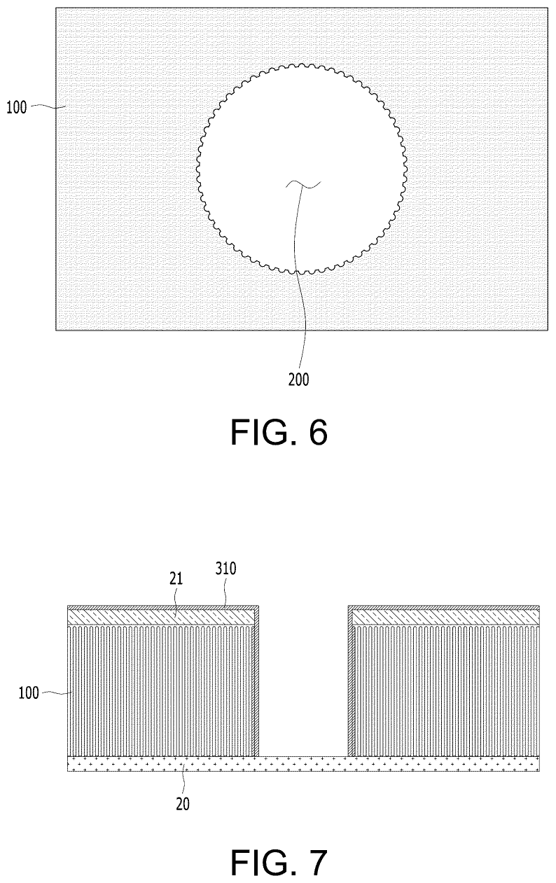

FIG. 5 is a view illustrating the perforated hole 200 is formed by removing the body 100 made of the anodic oxidation film in the opening area 22 using the etchant. FIG. 6 is a plan view illustrating the body 100 made of the anodic oxidation film in which the perforated hole 200 is formed.

The perforated hole 200 may be formed by wet-etching a part of the body 100 made of the anodic oxidation film. To this end, the anodic oxidation film exposed through the opening area 22 may react with the etchant to form the perforated hole 200. In forming the perforated hole 200, the etchant reacts selectively only with the anodic oxidation film. With the configuration of the pores 125, the perforated hole 200 is formed in the form of a vertical hole that is perforated in a direction parallel to the longitudinal direction of the pores 125.

As a result of forming the perforated hole 200, a plurality of fine trenches 88 in which a plurality of peaks and a plurality of valleys are repeated in the circumferential direction of the perforated hole 200 are formed on the inner wall of the perforated hole 200.

Then, the forming of the metal layer 300 on the inner wall of the perforated hole 200 is performed. The forming of the metal layer 300 includes (i) forming a first metal layer 310 on a surface of the patternable material 21 and the inner wall of the perforated hole 200, (ii) forming a second metal layer 320 on the first metal layer 310, and removing the patternable material 21 and the first metal layer 310 and the second metal layer 320 outside the perforated hole 200 so that the first metal layer 310 and the second metal layer 320 exist only inside the perforated hole 200.

First, the step of forming the first metal layer 310 on the surface of the patternable material 21 and the inner wall of the perforated hole 200 is performed.

The first metal layer 310 includes a vertical portion located toward a through-hole 400 and a planar portion located on an upper surface of the patternable material 21.

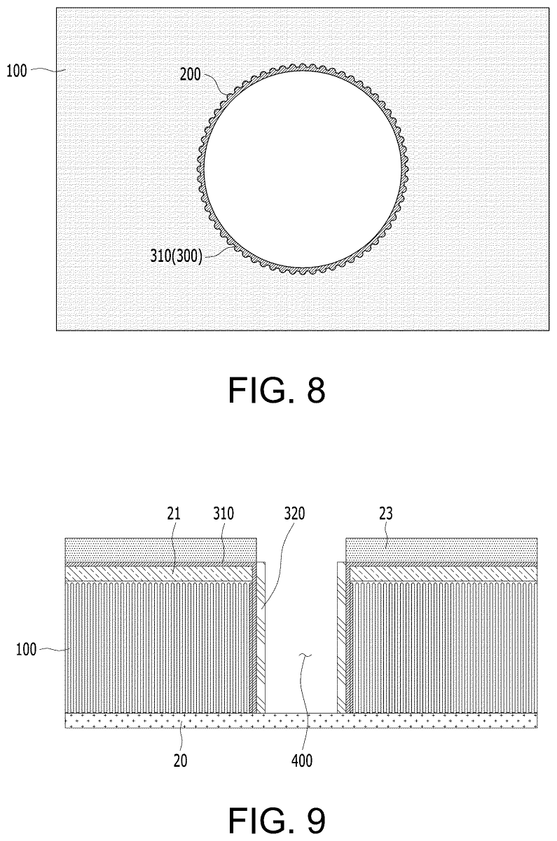

FIG. 7 is a view illustrating the first metal layer 310 is formed on the surface of the patternable material 21 and the inner wall of the perforated hole 200. FIG. 8 a plan view illustrating the first metal layer 310 is formed on the inner wall of the perforated hole 200.

The first metal layer 310 is formed to have a thickness in the range of 0.01 μm to 1 μm. The first metal layer 310 is made of a single layer or a plurality of layers of titanium (Ti), copper (Cu), gold (Au), or nickel (Ni). The first metal layer 310 may be formed using a thin film forming method such as electroless plating, sputtering, vacuum deposition, or ion plating. Preferably, the first metal layer 310 is formed by sputtering.

The first metal layer 310 fills the valleys of the fine trenches 88 formed on the inner wall of the perforated hole 200 and is also formed on the peaks of the fine trenches 88 to prevent the inner wall of the perforated hole 200 from being exposed toward the through-hole 400.

Then, the step of forming the second metal layer 320 on the first metal layer 310 so that the through-hole 400 is not closed is performed.

A masking 23 is provided on the first metal layer 310 located on the patternable material 21. The masking 23 functions to prevent the second metal layer 320 from being formed on an upper surface of the first metal layer 310 during a plating process of the second metal layer 320, which will be described later. The masking 23 is not provided on the through-hole 400. In other words, the masking 23 is not provided on the vertical portion of the first metal layer 310. On the other hand, the masking 23 is provided on the planar portion of the first metal layer 310, which is an area without the through-hole 400.

After providing the masking 23, the second metal layer 320 is formed by electroplating using the first metal layer 310. The second metal layer is formed on the surface of the vertical portion of the first metal layer 310 and is not provided on the planar portion of the first metal layer 310.

As a result of forming the second metal layer 320, the through-hole 400 having a smaller inner width than the perforated hole 200 is provided.

The second metal layer 320 may be made of at least one metal selected from: the group consisting of rhodium (Rd), platinum (Pt), iridium (Ir), palladium (Pd), nickel (Ni), manganese (Mn), tungsten (W), phosphorus (Ph), titanium (Ti), cobalt (Co), copper (Cu), silver (Ag), gold (Au), and an alloy of these metals; the group consisting of a palladium-cobalt (PdCo) alloy and a palladium-nickel (PdNi) alloy: or the group consisting of a nickel-phosphorus (NiPh) alloy, a nickel-manganese (NiMn) alloy, a nickel-cobalt (NiCo) alloy, and a nickel-tungsten (NiW) alloy.

Then, the step of removing the patternable material 21 and the first metal layer 310 and the second metal layer 320 outside the through-hole 400 so that the first metal layer 310 and the second metal layer 320 exist only inside the through-hole 400 is performed.

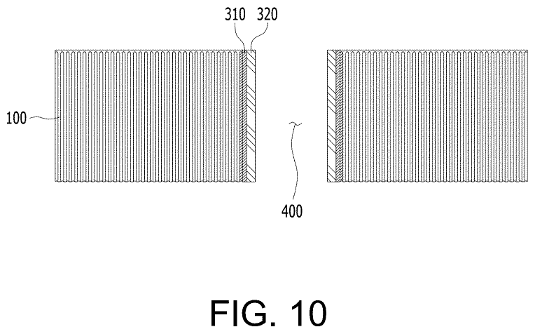

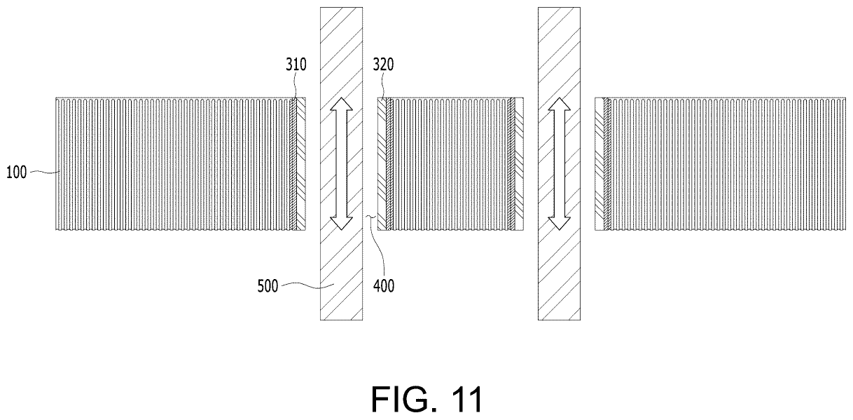

FIG. 10 is a view illustrating the first metal layer 310 and the second metal layer 320 are formed only in the through-hole 400.

After removing the patternable material 21 by stripping, a planarization process (CMP) is performed to remove the first metal layer 310 and the second metal layer 320 protruding from an upper surface of the body 100. As a result, the first metal layer 310 is formed on an inner wall of the through-hole 400, and the second metal layer 320 is formed on an inner wall of the first metal layer 310. The perforated hole 200 that is not filled by the first and second metal layers 310 and 320 becomes the through-hole 400.

The first metal layer 310 is provided between the inner wall of the perforated hole 200 and the second metal layer 320 to ensure that the second metal layer 320 is firmly coupled to the body 100. The second metal layer 320 improves the mechanical and/or electrical characteristics of the perforated hole 200. As described above, the mechanical and/or electrical characteristics of the perforated hole 200 can be improved through the configuration of the first metal layer 310 and the second metal layer 320.

FIG. 11 is a view illustrating the insertion member 500 is inserted into the through-hole 400.

The insertion member 500 is installed to be slidable vertically inside the through-hole 400. Here, an outer surface of the insertion member 500 comes into continuous contact with the inner wall of the through-hole 400. Since the inner wall of the through-hole 400 is covered by the metal layer 300, the body 100 made of the anodic oxidation film does not make direct contact with the insertion member 500. The inner wall of the through-hole 400 covered by the metal layer 300 forms a current path, and it is prevented from being easily worn even during sliding friction with the insertion member 500.

The anodic oxidation film structure 10 may be provided by stacking a plurality of bodies 100. With this, sufficient thickness can be secured, thereby improving the mechanical rigidity of the body 100.

The anodic oxidation film structure 10 according to the preferred embodiment of the present disclosure may be a guide plate of a probe card. In this case, the insertion member 500 is a probe pin.

The probe card includes a circuit board, a space transformer provided under the circuit board, and a probe head 4 provided under the space transformer. The probe head includes a plurality of probe pins and a guide plate having a plurality of guide holes into which the probe pins are inserted. The probe head includes an upper guide plate and a lower guide plate. The upper guide plate and the lower guide plate are fixedly installed through a spacer. The probe pins have a structure that elastically deform between the upper and lower guide plates.

The anodic oxidation film structure 10 according to the preferred embodiment of the present disclosure functions as at least one of the upper guide plate and the lower guide plate of the probe card to guide raising and lowering of the probe pin, which is the insertion member 500. In this case, the metal layer 300 constituting the anodic oxidation film structure 10 may be made of a metal having high wear resistance to prevent brittle fracture of the anodic oxidation film structure 10 and minimize the generation of particles during sliding contact.

The anodic oxidation film structure 10, in which the perforated hole 200 is mechanically and/or electrically reinforced by the metal layer 300, may be used in various fields other than the guide plates of the probe card described above.

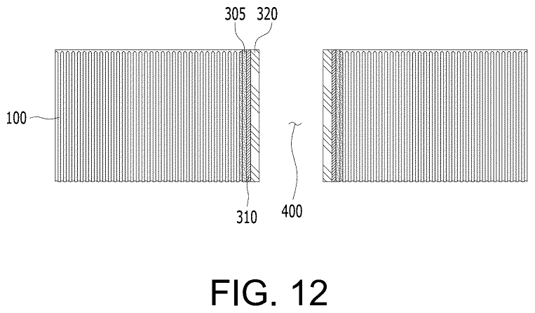

FIG. 12 is a view illustrating a bonding layer 305 is formed inside the first metal layer according to the preferred embodiment of the present disclosure.

The bonding layer 305 is provided between the body 100 made of the anodic oxidation film and the metal layer 300. More specifically, the bonding layer 305 is provided between the body 100 made of the anodic oxidation film and the first metal layer 310.

The bonding layer 305 functions to minimize peeling of the metal layer 300 from the body 100 made of the anodic oxidation film by improving the bonding force between the body 100 made of the anodic oxidation film and the metal layer 300.

The bonding layer 305 may have a coefficient of thermal expansion that is between that of the body 100 made of the anodic oxidation film and that of the metal layer 300. With this, peeling of the metal layer 300 from the body 100 made of the anodic oxidation film due to a difference in coefficient of thermal expansion can be minimized.

The bonding layer 305 may include metal oxide materials, such as NiO, HfO₂, ZrO₂, CuO₂, TaO₂, Ta₂O₅, TiO₂, and SiO₂, and may be formed by sputtering or sol-gel method.

Although the exemplary embodiments of the present disclosure have been described for illustrative purposes, those skilled in the art will appreciate that various modifications, additions, and substitutions are possible, without departing from the scope and spirit of the present disclosure as disclosed in the accompanying claims.

### DESCRIPTION OF THE REFERENCE NUMERALS IN THE DRAWINGS

10: anodic oxidation film structure
100: body
200: perforated hole
300: metal layer
400: through-hole
500: insertion member

What is claimed is:

1. An anodic oxidation film structure, comprising:
a body made of an anodic oxidation film formed by anodic oxidation of a base metal and then removing the base metal;
a perforated hole formed through the body and having a larger inner width than pores formed during the anodic oxidation; and
a metal layer provided on an inner wall of the perforated hole.

2. The anodic oxidation film structure of claim 1, wherein the metal layer comprises:
a first metal layer provided on the inner wall of the perforated hole; and
a second metal layer provided on an inner wall of the first metal layer.

3. The anodic oxidation film structure of claim 2, wherein the inner wall of the perforated hole is provided with a plurality of fine trenches in which a plurality of peaks and a plurality of valleys are repeated in a circumferential direction of the perforated hole, wherein the first metal layer entirely covers the fine trenches.

4. The anodic oxidation film structure of claim 2, wherein the first metal layer is made of a single layer or a plurality of layers of titanium (Ti), copper (Cu), gold (Au), or nickel (Ni).

5. The anodic oxidation film structure of claim 2, wherein the second metal layer is made of at least one metal selected from: the group consisting of rhodium (Rd), platinum (Pt), iridium (Ir), palladium (Pd), nickel (Ni), manganese (Mn), tungsten (W), phosphorus (Ph), cobalt (Co), and an alloy of these metals; the group consisting of a palladium-cobalt (PdCo) alloy and a palladium-nickel (PdNi) alloy: the group consisting of a nickel-phosphorus (NiPh) alloy, a nickel-manganese (NiMn) alloy, a nickel-cobalt (NiCo) alloy, and a nickel-tungsten (NiW) alloy: or the group consisting of copper (Cu), silver (Ag), gold (Au), and an alloy of these metals.

6. A method manufacturing an anodic oxidation film structure, the method comprising:
forming a perforated hole in a body made of an anodic oxidation film; and
forming a metal layer on an inner wall of the perforated hole.

7. The method of claim 6, wherein the forming of the perforated hole in the body made of the anodic oxidation film comprises:
forming an opening area by forming a patternable material on a surface of the body made of the anodic oxidation film and then patterning the patternable material; and
forming the perforated hole by removing the body made of the anodic oxidation film in the opening area using an etchant.

8. The method of claim 7, wherein the forming of the metal layer comprises:
forming a first metal layer on a surface of the patternable material and the inner wall of the perforated hole;
forming a second metal layer on the first metal layer so that a through-hole is provided; and
removing the patternable material and the first metal layer and the second metal layer outside the through-hole so that the first metal layer and the second metal layer exist only inside the through-hole.
